(19) United States
(12) Patent Application Publication
(10) Pub. No.: US 2018/0146302 A1
(43) Pub. Date: May 24, 2018

(54) MEMS MICROPHONE PACKAGE STRUCTURE AND METHOD FOR MANUFACTURING THE MEMS MICROPHONE PACKAGE STRUCTURES

(71) Applicant: MERRY ELECTRONICS (SHENZHEN) CO., LTD., Shenzhen (CN)

(72) Inventors: Jen-Yi CHEN, Taichung City (TW); Chao-Sen CHANG, Taichung City (TW); Chun-Chieh WANG, Taichung City (TW); Yong-Shiang CHANG, Taichung City (TW)

(21) Appl. No.: 15/857,709

(22) Filed: Dec. 29, 2017

Related U.S. Application Data
(63) Continuation-in-part of application No. 14/840,365, filed on Aug. 31, 2015.
Application No. 14/840,365 is a continuation-in-part of application No. 14/448,461, filed on Jul. 31, 2014, now Pat. No. 9,162,869.

(51) Int. Cl. H04R 19/04; B81B 3/00; B81B 7/00; H04R 19/00

(52) U.S. Cl. CPC H04R 19/04; B81B 3/0021; B81B 2207/096; H04R 19/005; B81B 2201/0257; B81B 7/0032

(57) ABSTRACT

A MEMS microphone package structure is provided to have a circuit substrate, an acoustic wave transducer, an application-specific integrated circuit, a lid, and at least two solder pads. The circuit substrate has a top surface, a bottom surface, and a sound hole passing through the top surface and the bottom surface. The acoustic wave transducer and the application-specific integrated circuit are disposed on the top surface and electrically connected. The lid is disposed on the top surface and made by a multilayer printed circuit boards. The lid surrounds and covers the acoustic wave transducer and the application-specific integrated circuit. The lid further has a shielding layer completely disposed on inner surfaces of the lid and two embedded first metal layers served for signal transmission and grounding and electrically connected with the solder pads respectively.

### CROSS-REFERENCE TO RELATED APPLICATION

This application is a continuation in part of U.S. patent application Ser. No. 14/840,365 filed on Aug. 31, 2015, which is a continuation in part of U.S. patent application Ser. No. 14/448,461 filed on Jul. 31, 2014, now U.S. Pat. No. 9,162,869, the contents of which are hereby incorporated by reference in their entirety.

### BACKGROUND OF THE INVENTION

### 1. Field of the Invention

The present invention relates to MEMS microphone technology, and more particularly, to a MEMS microphone package structure having a non-planar substrate that has a peripheral wall upwardly extended from a periphery of a top surface of said bearing base to maintain the overall structural strength, enabling the MEMS microphone package structure have a low profile characteristic.

### 2. Description of the Related Art

Compared to conventional microphones, MEMS microphones have compact size, power and price advantages, and therefore, MEMS (Micro-electromechanical Systems) microphones have been widely used in mobile phones and other electronic products. A conventional MEMS microphone package structure 70, as shown in FIG. 1, generally comprises a substrate 71, an acoustic wave transducer 72 and an application-specific integrated circuit 73 (ASIC) arranged on the substrate 71 and electrically coupled together, a plurality of electric connection structures 76 mounted in the substrate 71 for electrically connecting the application-specific integrated circuit 73 to external devices, a back cover 74 covered on the substrate 71 for protecting the internal components of the microphone. As illustrated in FIG. 1, the substrate 71 of the

MEMS microphone package structure 70 bears the pressure of the acoustic wave transducer 72 and the application-specific integrated circuit 73. Therefore, in consideration of the structural strength, the substrate 71 must have a certain thickness. This factor is unfavorable to the low profile trend of the development of today's electro-acoustic products. For making a MEMS microphone package structure 70 having a low profile characteristic, subject to restriction of the internal components, the volume of the cavity 75 of the microphone is minimized. Thus, reducing the thickness of the substrate 71 is helpful to extend the volume of the cavity 75 and to enhance the acoustic performance of receiving sensitivity and signal to noise ratio of the microphone.

Further, US 2014/0037115A1 discloses a MEMS assembly. As illustrated in FIG. 2, the MEMS assembly is a three-layer structure which including a lid 102, a wall 104 and a base 106. The lid 102 has an acoustic port or opening 112. The MEMS apparatus, referenced by 108, and the IC, referenced by 110, are mounted at the lid 102. A solder region 160 is defined on a top and a bottom surface of the wall 104. The solder region is covered by solder material such that the wall 102 can be physically and electrically connected to the lid 102 and the base 106.

According to the aforesaid patent, the base 106 also needs to bear the pressure given by the lid 102, the MEMS apparatus 108, the IC 110 and the wall portion 104, and thus, the base 106 cannot be made too thin. Further, because the wall portion 104 uses solder material to electrically connect the lid 102 and the base 106, in the conventional packaging process, it needs to coat the top surface of the wall portion 104 with the solder material, reverse the wall portion 104, and then to coat the opposing bottom surface of the wall portion 104 with the solder material after reversed the wall portion 104. After the coating process, the positioning and connection of the wall portion 104 and the base 106 can then be performed. This packaging process is complicated and its cost is high. The structural strength of the soldered MEMS assembly is still low and easy to break.

### SUMMARY OF THE INVENTION

The present invention has been accomplished under the circumstances in view. It is an object of the present invention to provide a MEMS microphone package structure, which can increase the volume of the cavity of the microphone without changing its external dimension and, which provides protection against electromagnetic interference.

It is another object to provide a MEMS microphone package structure, which can provide better protection against electromagnetic interference.

To achieve this and other objects of the invention, a MEMS microphone package structure is provided to comprise a non-planar substrate, a lid, an acoustic wave transducer, an application-specific integrated circuit, and at least one solder pad. The at least one solder pad is mounted at the top side of the lid or the outer surface of the non-planar substrate. The non-planar substrate is a laminated structure of multiple printed circuit boards, comprising a first metal layer, a base, and a peripheral wall that extends from the base around the border thereof. Thus, the lid can be covered on the non-planar substrate and connected to the peripheral wall, defining with the non-planar substrate a cavity. Further, the acoustic wave transducer is mounted in the cavity. Further, a sound hole is selectively formed in the non-planar substrate or the lid.

Thus, the peripheral wall reinforces the overall structural strength of the non-planar substrate so that the bearing base of the non-planar substrate can be designed relatively thinner to provide a low profile characteristic, and the volume of the cavity of the microphone can be maximized without changing the external dimension of the MEMS microphone package structure Other and further benefits, advantages and features of the present invention will be understood by reference to the following specification in conjunction with the accompanying drawings, in which like reference characters denote like elements of structure.

### BRIEF DESCRIPTION OF THE DRAWINGS

FIG. 1 is a sectional view of a conventional MEMS microphone package structure.

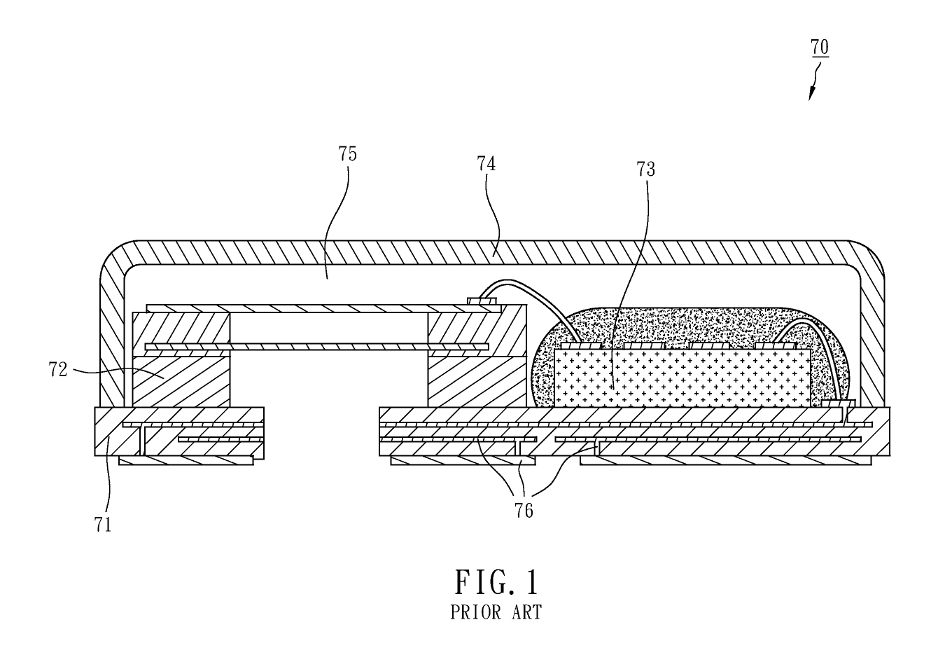

FIG. 2 is a sectional view of a MEMS microphone package structure in accordance with a first embodiment of the present invention.

FIG. 3 is a sectional view of a MEMS microphone package structure in accordance with a second embodiment of the present invention.

FIG. 4 is a MEMS microphone package structure manufacturing flow chart of the invention.

FIG. 5 is a sectional view of a MEMS microphone package structure in accordance with a third embodiment of the present invention.

FIG. 6 is another sectional view of the MEMS microphone package structure in accordance with a third embodiment of the present invention, illustrating an alternate form of the lid.

FIG. 7 is still another sectional view of the MEMS microphone package structure in accordance with the third embodiment of the present invention, illustrating another alternate form of the lid.

FIG. 8 is a sectional view of a MEMS microphone package structure in accordance with a fourth embodiment of the present invention.

FIG. 9 is a sectional view of a MEMS microphone package structure in accordance with a fifth embodiment of the present invention.

FIG. 10 is a sectional view of a MEMS microphone package structure in accordance with a sixth embodiment of the present invention.

FIG. 11 is an elevational view of the non-planar substrate of the MEMS microphone package structure in accordance with the sixth embodiment of the present invention.

FIG. 12 is a sectional view of a MEMS microphone package structure in accordance with a seventh embodiment of the present invention.

FIG. 13 is an exploded view of the MEMS microphone package structure in accordance with the seventh embodiment of the present invention.

FIG. 14 is a flow chart of the method for manufacturing the MEMS microphone package structure.

### DETAILED DESCRIPTION OF THE INVENTION

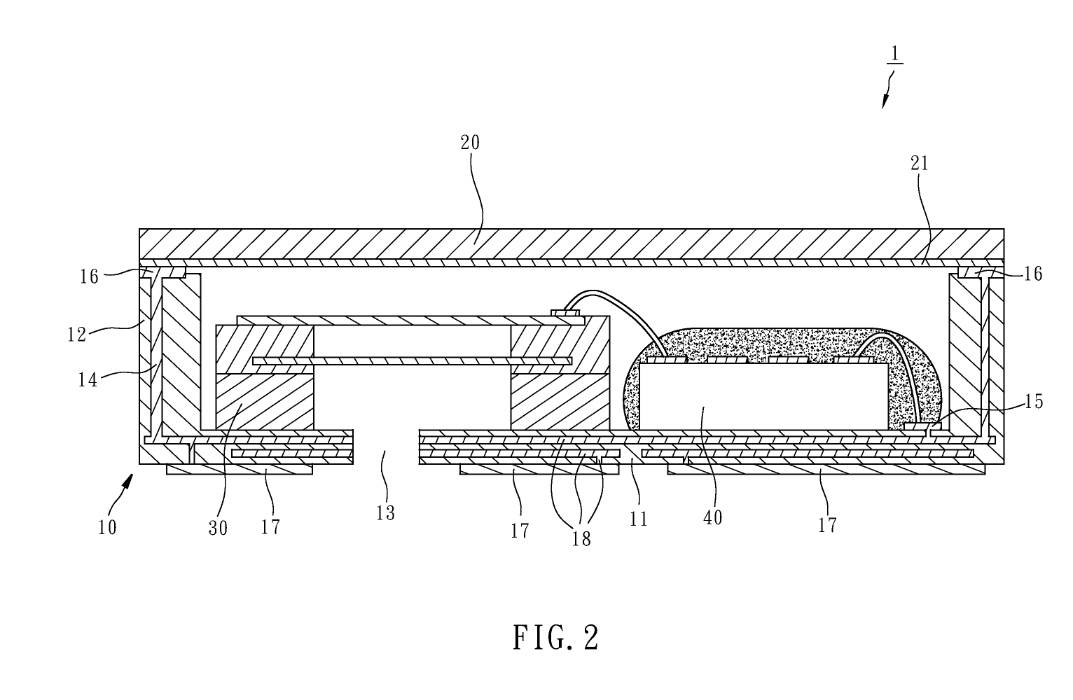

For better understanding of the benefits, advantages and features of the present invention, a MEMS (micro-electromechanical system) microphone package structure having a non-planar substrate in accordance with a first embodiment is described herein after with reference to FIG. 2. As illustrated, the MEMS microphone package structure 1 comprises a non-planar substrate 10, a lid 20, and an acoustic wave transducer 30. The structural details of these component parts and their relative relationship are described hereinafter.

The non-planar substrate 10 is a multilayer printed circuit board with a cavity (Cavity PCB), having multiple circuit layers (not shown) and insulation layers (not shown) continuously laminated thereon and pressed and adhered in integrity to exhibit a U-shaped configuration by means of the implementation of a PCB manufacturing process. The non-planar substrate 10 comprises a bearing base 11 and a peripheral wall 12. The peripheral wall 12 is made in one piece and it is surrounded and upwardly extended from a periphery of a top surface of the bearing base 11. The peripheral wall 12 has an outer lateral surface P1. Further, wiring electrodes 15 and metal bumps 17 are respectively arranged on opposing top and bottom surfaces of the bearing base 11. The bearing base 11 has a sound hole 13 located therein for the passing of acoustic waves. The bearing base 11 has a plurality of electric connection structures 18, such as metal wirings and blind via holes (BVH), arranged therein for conducting the metal bumps 17 and the wiring electrode 15, so that the MEMS microphone package structure 1 can be electrically connected with external devices via the metal bumps 17. The peripheral wall 12 has an electrical conduction path formed therein, which is a first metal layer 14 formed via blind hole, plating or copper plughole techniques. In this embodiment, the first metal layer 14 is embedded in the peripheral wall 12. The peripheral wall 12 has a metal bump 16 arranged on a top surface thereof and electrically connected with the first metal layer 14. The non-planar substrate 10 may be made integrally from the material, including but not limited to glass substrate (e.g. FR-4), plastic substrate (e.g. LCP), or ceramic substrate.

The lid 20 is a flat panel member made of an insulative material (such as plastics) and includes a second metal layer 21 arranged on a bottom surface thereof. The lid 20 is covered on the non-planar substrate 10 and connected with the peripheral wall 12 so that the lid 20 and the non-planar substrate 10 define therebetween a cavity 26. The lid 20 has an outer lateral surface P2 which is substantially flush with the outer lateral surface P1 of the peripheral wall 12 of the non-planar substrate 10. After connecting the lid 20 and the non-planar substrate 10, the second metal layer 21 is electrically connected to the first metal layer 14 through the metal bump 16 at the top surface of the peripheral wall 12, so that the non-planar substrate 10 can be grounded to provide an electromagnetic shielding structure 50, thus, the first metal layer 14 and the second metal layer 21 can fully shield the microphone against electromagnetic interference.

It's worth mentioning that the lid 20 can be a metal member electrically connected to the first metal layer 14 alternatively, thereby achieving the desired electromagnetic interference shielding effect. In the present disclosure, the first metal layer 14 is adapted for grounding (i.e., works as a part of the grounded conductive path). In one or more embodiments described below, two first metal layers 14 may be provided, and selectively adapted for inputting or outputting electrical signals of internal devices in the MEMS microphone package structure 1 (to work as a part of the signal transmission path). Further, the structure of the first metal layer 14 is not limited to the design of the above-described “layered structure”, it may be of other design, such as silicon via structure.

The acoustic wave transducer 30 is bonded to the top surface of the bearing base 11 and disposed inside the cavity 26 corresponding to the sound hole 13. An application-specific integrated circuit (ASIC) 40 is bonded to the top surface of the bearing base 11 and disposed inside the cavity 26 between the acoustic wave transducer 30 and the peripheral wall 12. The acoustic wave transducer 30 is electrically connected to the application-specific integrated circuit 40 by wire bonding. Further, the application-specific integrated circuit 40 is electrically connected with the wiring electrodes 15 at the top surface of the bearing base 11 by wire bonding.

In application, the structure of the peripheral wall 12 enhances the overall strength of the non-planar substrate 10. When compared to conventional MEMS microphone package structures, the bearing base 11 of the non-planar substrate 10 can be designed relatively thinner, enabling the MEMS microphone package structure 1 to have a low profile characteristic, increasing the volume of the cavity 26 to enhance the acoustic performance of receiving sensitivity and signal to noise ratio of the microphone without changing the external dimension of the MEMS microphone package structure 1. Further, forming the peripheral wall 12 on the bearing base 11 in integration greatly enhances the overall strength of the non-planar substrate 10. The electrical conduction path can be directly formed in the one-piece non-planar substrate 10, eliminating the drawbacks of the complicated conventional multi-layer PCB manufacturing process that needs to make holes in each layer and then bond the multiple layers together.

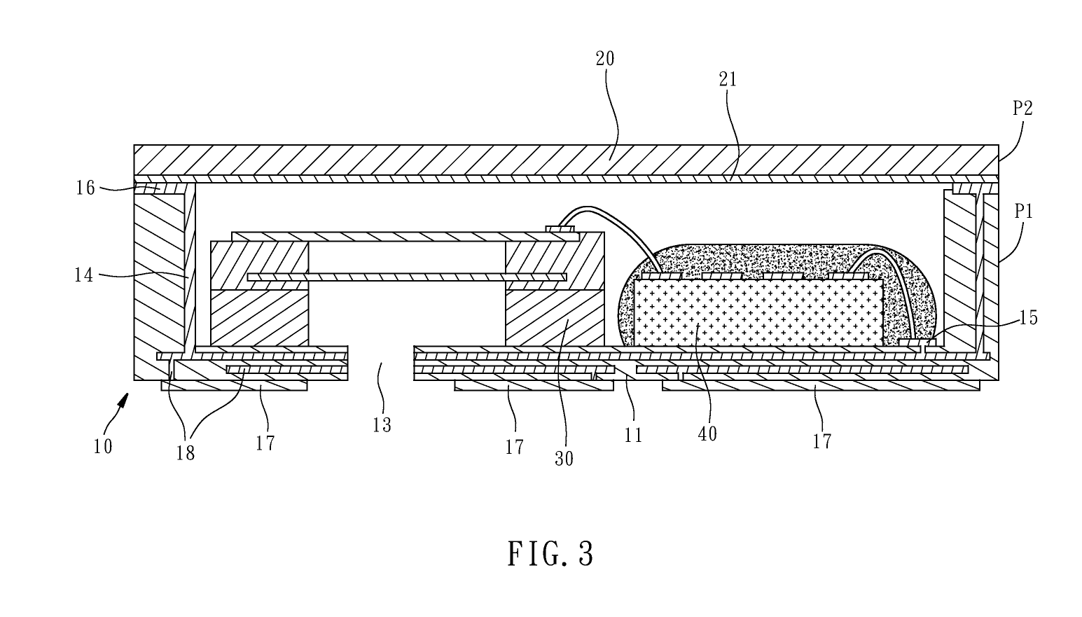

FIG. 3 illustrates an alternative MEMS microphone package structure in accordance with a second embodiment. This second embodiment is substantially similar to the aforesaid first embodiment with one of the difference that a part of the first metal layer 14 is plated on the inner surface of the peripheral wall 12 by electroplating. Similarly, the first metal layer 14 has a metal bump 16 located at a top side thereof and electrically connected with the second metal layer 21. Further, the bottom end of the first metal layer 14 is electrically connected to the bearing base 11. Thus, the bearing base 11 has low profile and electromagnetic interference shielding characteristics.

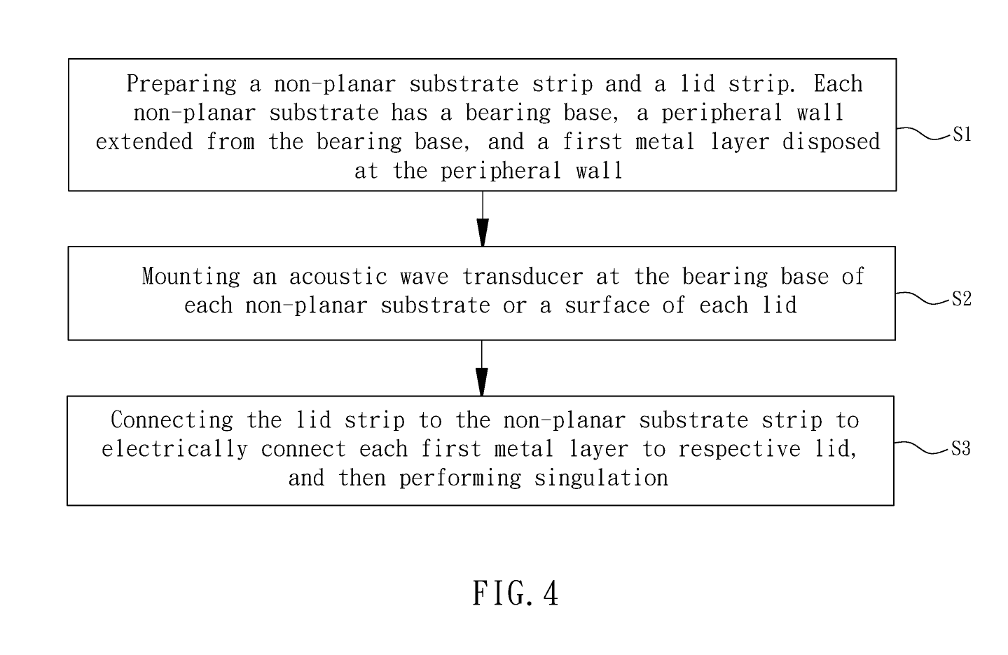

Further, the invention has the advantage of ease of mass production. The fabrication of the MEMS microphone package structure in accordance with the present disclosure is described hereinafter with reference to the manufacturing flow chart of FIG. 4.

At first, perform Step 51: Prepare a non-planar substrate strip of an array of non-planar substrates 10 and a lid strip of an array of lids 20, wherein each non-planar substrate 10 comprises a bearing base 11, a peripheral wall 12 surrounded and extended from a top surface of the bearing base 11 along a periphery thereof, a first metal layer 14 located at the peripheral wall 12 and a sound hole 13 formed at the bearing base 11 or lid 20. It is to be noted that, in Step 51, the design of the peripheral wall 12 enhances the structural strength of the respective non-planar substrate 10, so that a large area non-planar substrate strip can be made, avoiding warping, enhancing process efficiency and reducing costs.

Thereafter, proceed to Step S2: Mount an acoustic wave transducer 30 and a application-specific integrated circuit 40 at the bearing base 11 of each non-planar substrate 10 to make each acoustic wave transducer 30 disposed above the associating sound hole 13, and then employ a wire bonding technique to electrically connect each acoustic wave transducer 30 to the respective application-specific integrated circuit 40 and also to electrically connect each application-specific integrated circuits 40 to the respective bearing base 11.

It is to be noted that, as an alternate form of the invention, the application-specific integrated circuit 40 may be arranged on the surface of the lid 20.

At final, proceed to Step S3: Connect the lid strip to the non-planar substrate strip to make each first metal layer 14 electrically connected with the respective lid 20, and then employ a singulation process to separate the material thus processed into individual MEMS microphone package structure 1.

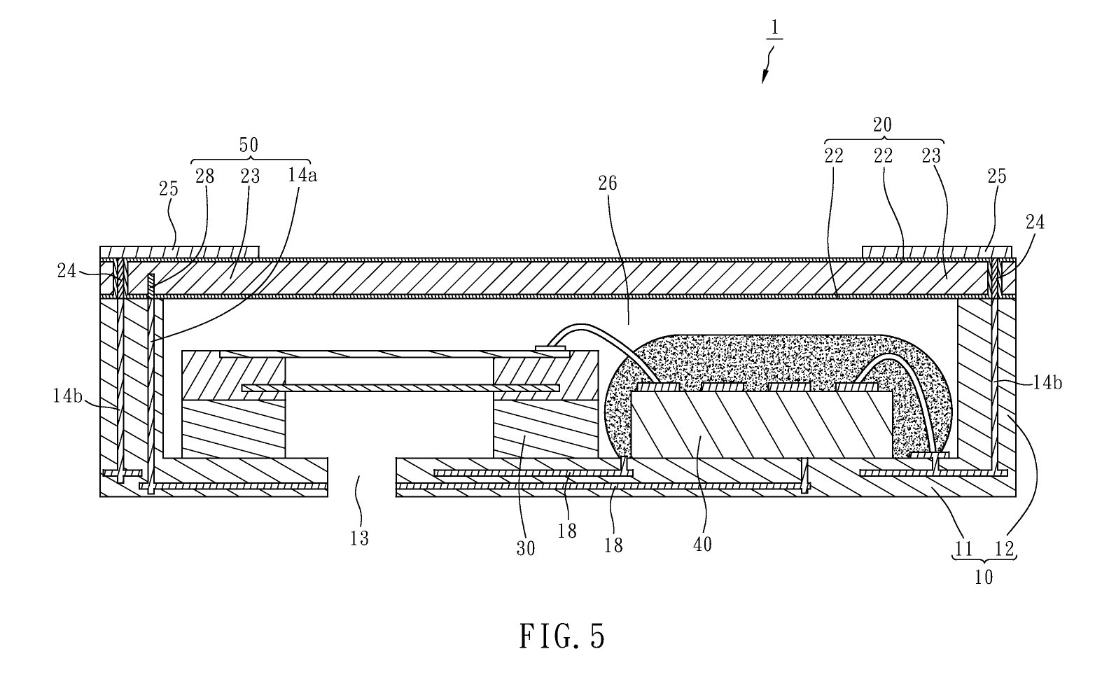

FIG. 5 illustrates a MEMS microphone package structure in accordance with a third embodiment. In this third embodiment, in addition to one first metal layer 14a, the peripheral wall 12 of the non-planar substrate 10 has another first metal layer 14b mounted therein in a juxtaposed manner and electrically connected to the acoustic wave transducer 30 and the application-specific integrated circuit 40.

Further, the lid 20 is a metal substrate comprising an insulation layer 22, a metal base material 23 and an insulation layer 22 laminated together. The number of layers of the metal base material 23 may be increased according to requirements but not limited to the configuration of this embodiment. Alternatively, the structure of the metal substrate may be formed of a metal base material 23, and insulation layer 22 and a metal base material 23 using lamination. Through-silicon vias 24 are formed in the peripheral area of the lid 20 that is bonded to the peripheral wall 12 of the non-planar substrate 10, and electrically connected to solder pads 25 at the top surface of the lid 20. Thus, after connection between the lid 20 and the peripheral wall 12 of the non-planar substrate 10, the first metal layer 14a is electrically connected to the metal base material 23 through the through-silicon vias 28, creating an electromagnetic shielding structure 50 to protect the acoustic wave transducer 30 and the application-specific integrated circuit 40 against electromagnetic interference. Further, the transmission of the input and output signals of the MEMS microphone package structure can be achieved by means of electrically connecting the first metal layer 14b, the through-silicon vias 24 and the solder pads 25.

When compared to conventional microphone package designs, the invention reinforces the strength of the structure between the bearing base 11 and the peripheral wall 12, allowing the first metal layer 14a and each first metal layer 14b to be directly formed in the peripheral wall 12. Thus, the present disclosure is suitable for the implementation of the non-planar substrate strip manufacturing process, simplifying the fabrication of the MEMS microphone package structure 1 and reducing the average unit cost. Further, because the structural strength of the non-planar substrate 10 is greatly enhanced, the bearing base 11 can be made relatively thinner, enabling the volume of the cavity 26 to be maximized.

Further, during fabrication of the MEMS microphone package structure 1, it is not necessary to reverse the non-planar substrate strip; the acoustic wave transducer 30 and the application-specific integrated circuit 40 can be directly soldered or wire-bonded to the bearing base 11, simplifying the fabrication and reducing the possibility of overflow of solder to the sound hole 13. Further, forming the sound hole 13 in the bearing base 11 is helpful to improvement of the sensitivity of the MEMS microphone package structure 1 and optimization of frequency response in the super wide band.

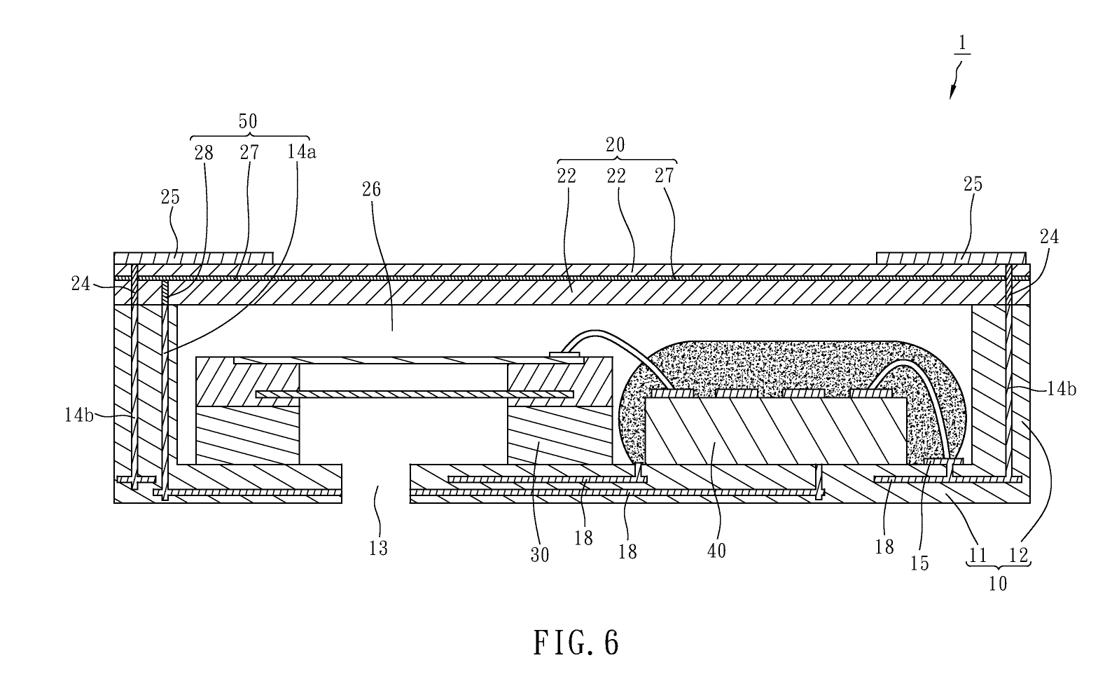

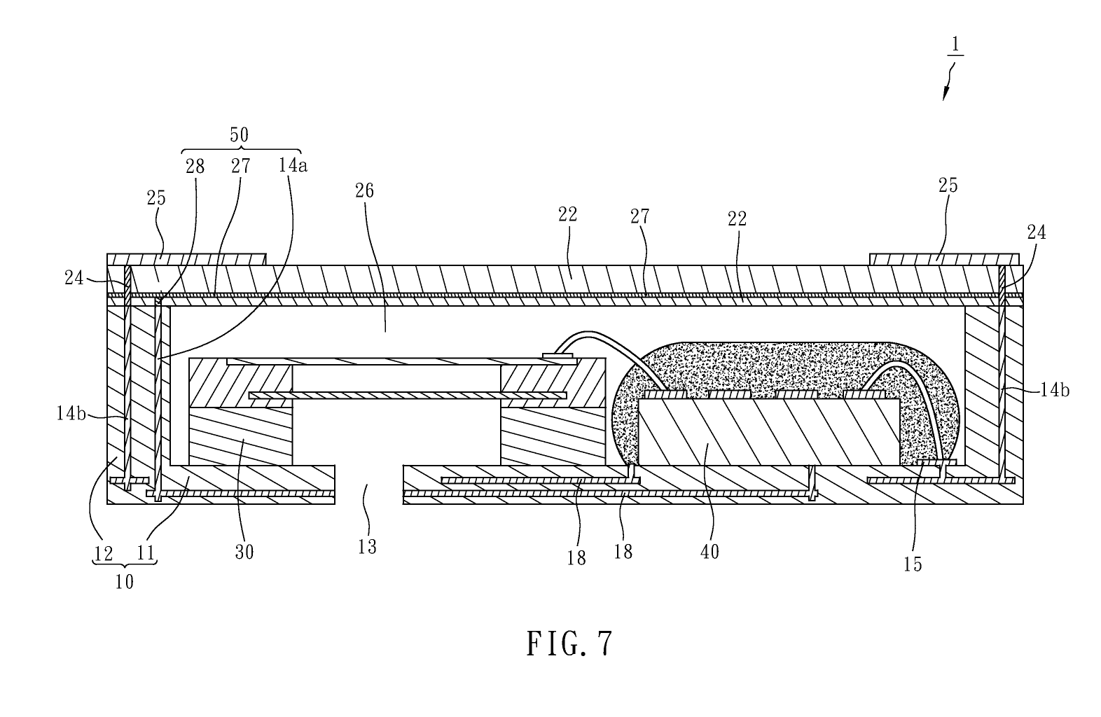

Further, the lid 20 may be made of fiberglass substrate or ceramic substrate, as illustrated in FIG. 6 and FIG. 7. In FIG. 6, the insulation layers 22 of the lid 20 are respectively formed of a fiberglass substrate and arranged on opposing top and bottom surface of a conductive layer 27 that is made of a copper foil. The conductive layer 27 is electrically connected with the first metal layer 14a through the through-silicon vias 28, forming an electromagnetic shielding structure. In FIG. 7, the insulation layer 22 at the top side of the conductive layer 27 (copper foil) is formed of a ceramic substrate, and the insulation layer 22 at the bottom side of the conductive layer 27 (copper foil) is made from polypropylene (PP).

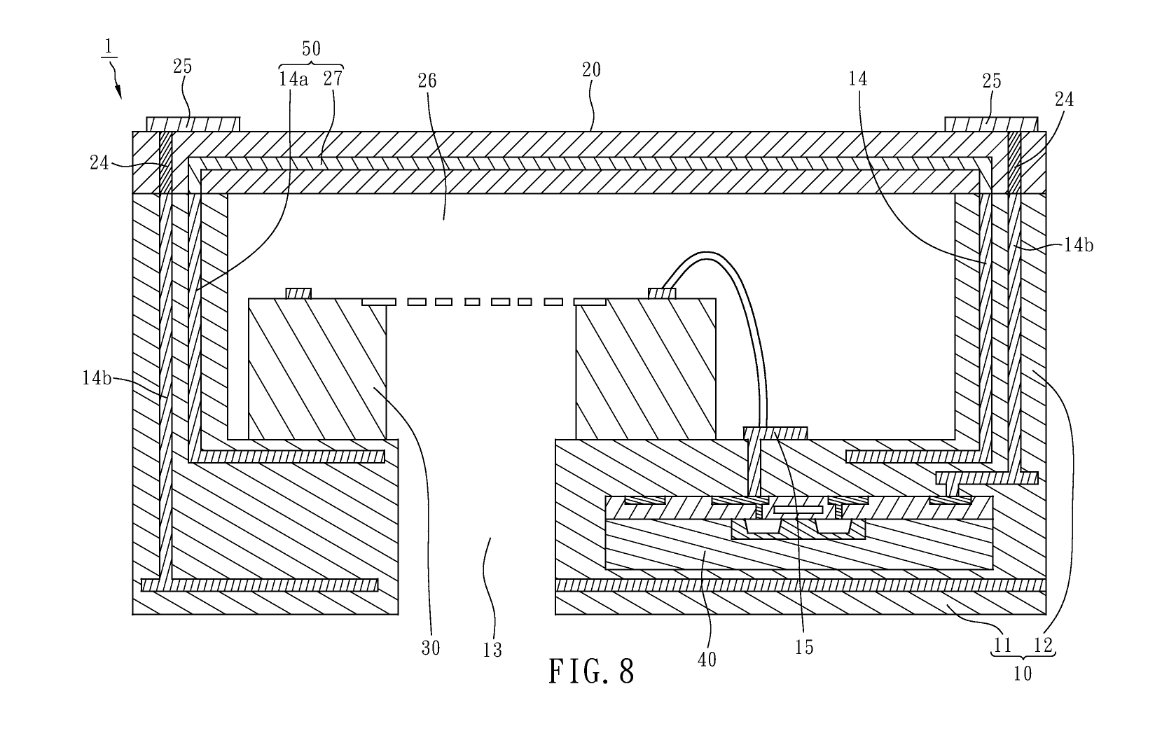

FIG. 8 illustrates a MEMS microphone package structure in accordance with a fourth embodiment. Unlike the aforesaid third embodiment, the application-specific integrated circuit 40 is embedded in the bearing base 11 using a semiconductor manufacturing process, enabling signals to be transmitted to the solder pads 25 through the first metal layer 14b and the through-silicon vias 24 and also increasing the volume of the cavity 26. Further, the first metal layer 14a can be electrically connected to the conductive layer 27 through the through-silicon vias 28, forming an electromagnetic shielding structure 50.

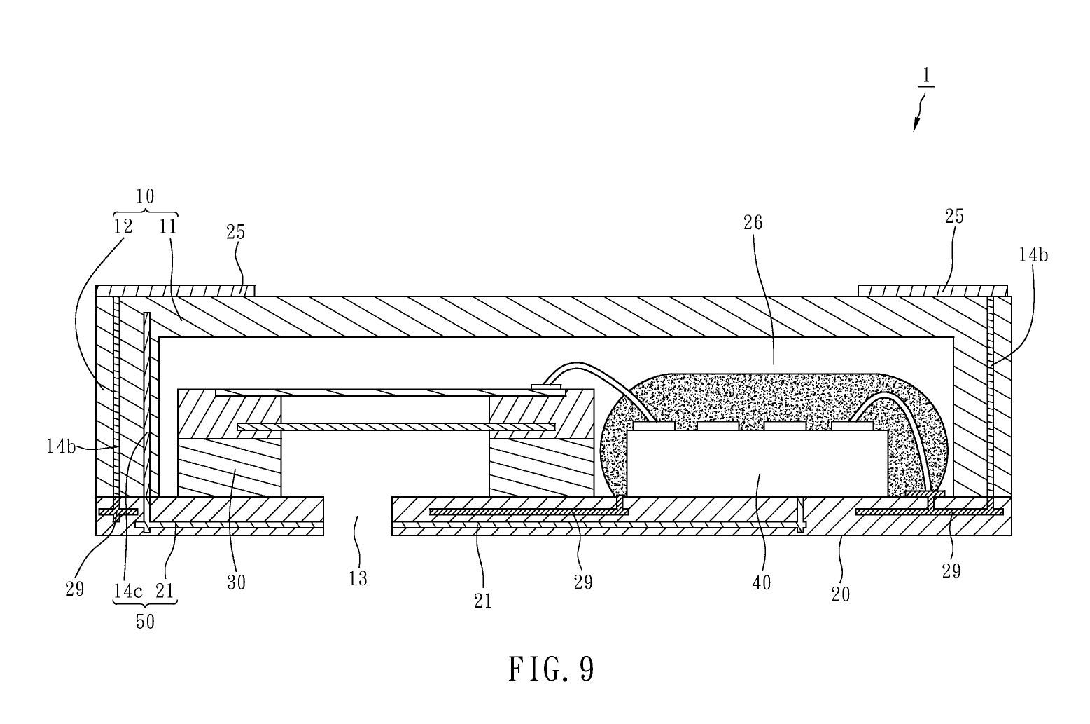

FIG. 9 illustrates a MEMS microphone package structure in accordance with a fifth embodiment. In the fifth embodiment, the acoustic wave transducer 30, the application-specific integrated circuit 40 and the sound hole 13 are located at the lid 20, and electrically connected to the solder pads 25 at the bearing base 11 through the electric connection structure 29 of the lid 20 and the first metal layer 14b of the peripheral wall 12, simplifying the circuit layout of the non-planar substrate 10, contributing to the thinning of the bearing base 11, and reducing the electrical wiring cost of the non-planar substrate 10.

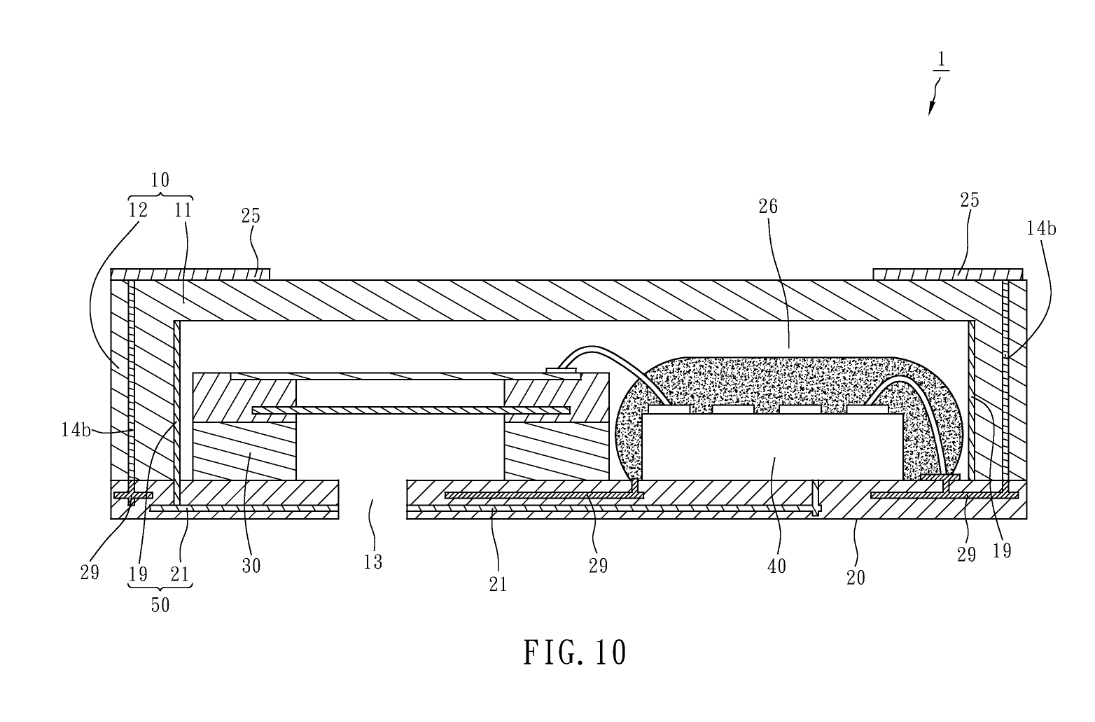

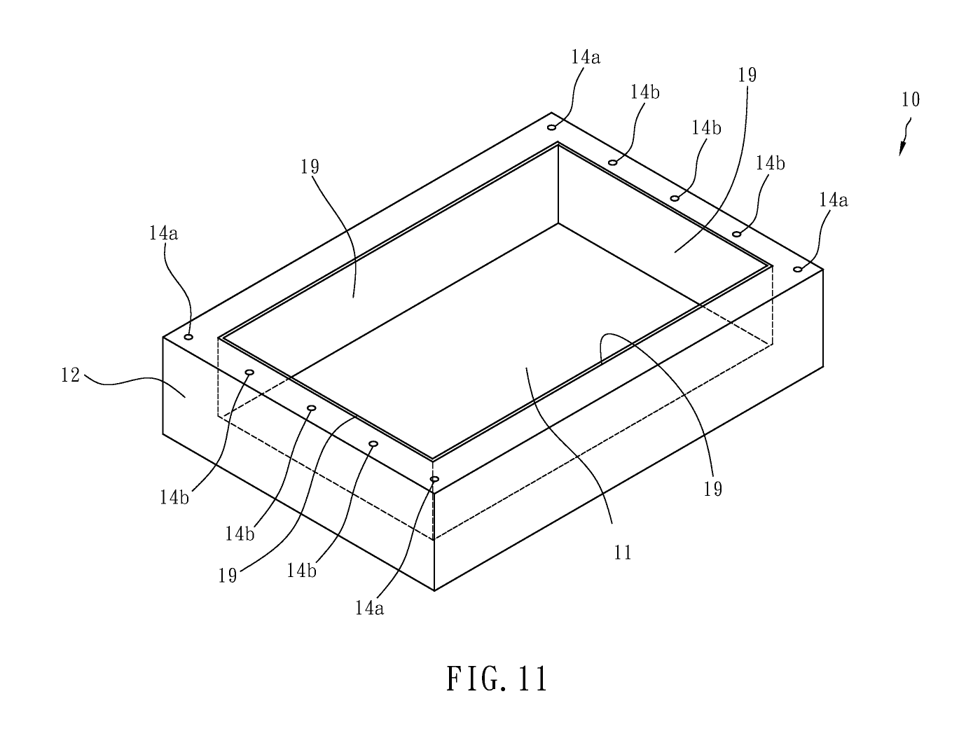

FIGS. 10 and 11 illustrate a MEMS microphone package structure in accordance with a sixth embodiment. In the sixth embodiment, an annular third metal layer 19 is formed on the inner four surfaces of the peripheral wall 12 of the non-planar substrate 10 by, for example, electroplating. The third metal layer 19 is electrically connected to the second metal layer 21 of the lid 20 to constitute a grounded conductive path. Further, the peripheral wall 12 has embedded therein a plurality of first metal layers 14a,14b of via hole design. The first metal layers 14a are located at the four corners of the peripheral wall 12 for electrically connecting to the second metal layer 21 of the lid 20. The first metal layers 14b are formed in the peripheral wall 12 at other locations and adapted to work as a signal transmission path, so that the input and/or output signals of the MEMS microphone package structure 1 can be transmitted through the first metal layer 14b and the solder pads 25 of the non-planar substrate 10.

It is to be noted that, in the sixth embodiment the first metal layer 14a and the third metal layer 19 are both used to constitute a grounded conductive path, effectively protecting the MEMS microphone package structure 1 against interference of external electromagnetic noises.

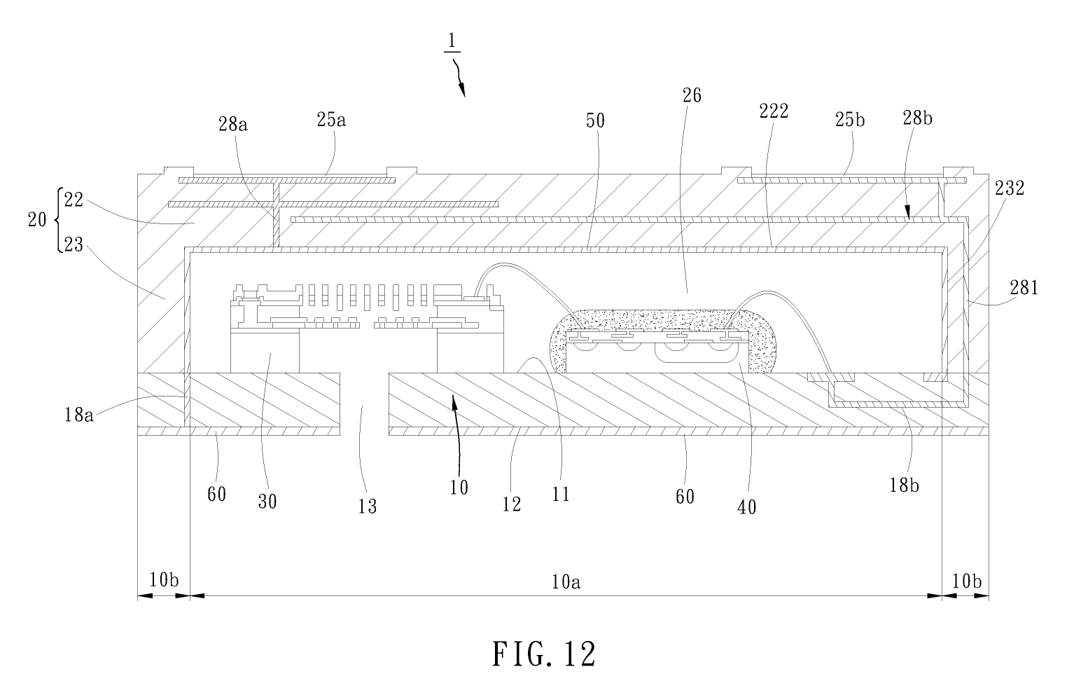

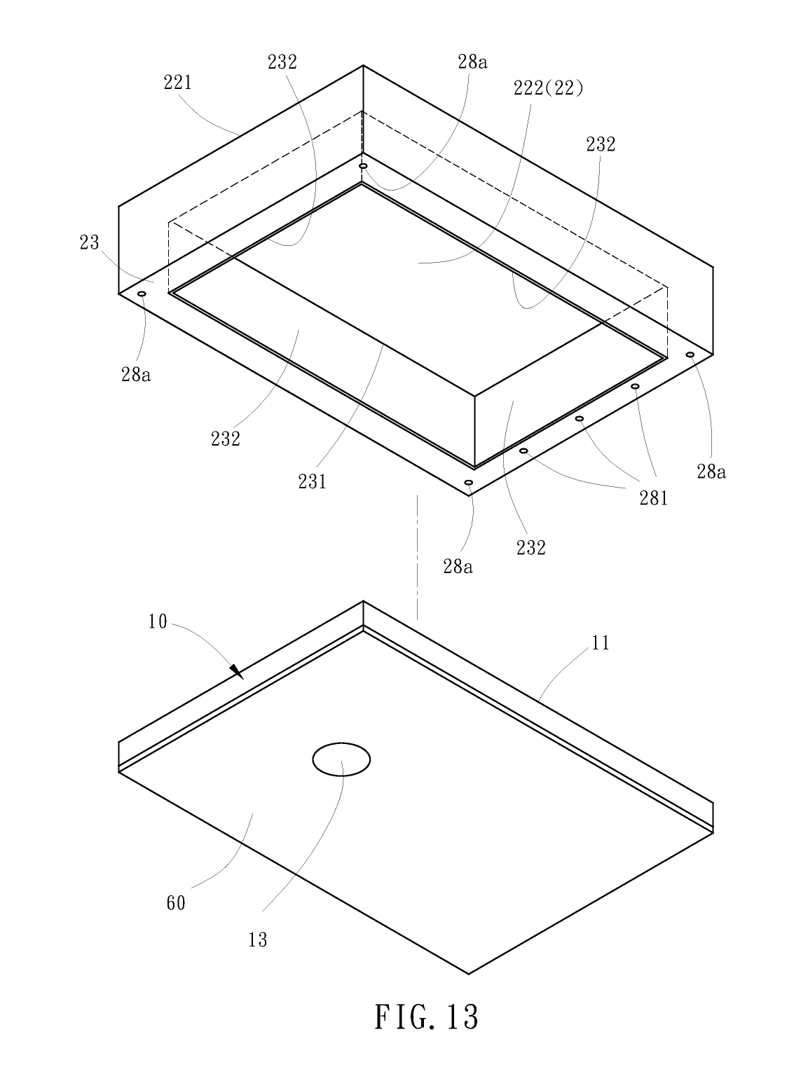

FIGS. 12 and 13 illustrate a MEMS microphone package structure 1 in accordance with a seventh embodiment. As illustrated, the MEMS microphone package structure 1 comprises a circuit substrate 10, a three-dimensional lid 20 (hereinafter “lid”), an acoustic wave transducer 30, application-specific integrated circuit 40 (hereinafter “ASIC”), a plurality of solder pads 25a, 25b, and a metallic shielding layer 60. The structural details of these component parts and their relative relationship are described as follows.

Referring to FIGS. 12 and 13, the circuit substrate 10 is a planar printed circuit board which has a top surface 11, a bottom surface 12, and a sound hole 13 passes through the top surface 11 and the bottom surface 12. The circuit substrate 10 comprises a central portion 10a and a peripheral portion 10b surrounding the central portion 10a. The central portion 10a is served for carrying the acoustic wave transducer 30 and the ASIC 40. The circuit substrate 10 further includes a plurality of embedded electric connection structures 18a,18b which may have a structure as metallic conducting layers, embedded vias, or metal pads. The electric connection structures 18a,18b and the metal pads may be arranged and designed according to required circuit layout. The electric connection structures 18a,18b may be made from the material, including but not limited to copper or god. The electric connection structures 18a,18b includes a signal transmission path 18b electrically connected with the ASIC 40 and a grounded path 18a electrically connected with the metallic shielding layer 60.

The lid 20 is mounted on the top surface 11 of the circuit substrate 10. The lid 20 is made by a multilayer printed circuit boards that are staked together. The lid 20 has a plate portion 22 and a peripheral wall 23 completely surrounding and downwardly extending from a periphery 221 of the plate portion 22. The plate portion 22 and the peripheral wall 23 jointly constitute a cavity 26 which is employed for accommodating the acoustic wave transducer 30 and the ASIC 40. The lid 20 has a plurality of inner surfaces (an inner top surface 222 and four inner lateral surface 232).

The inner top surface 222 is defined by an inner edge 231 of the peripheral wall 23. The inner top surface 222 completely covers the acoustic wave transducer 30 and the ASIC 40. The peripheral wall 23 has the four inner lateral surfaces 232 that are contiguous. The four inner lateral surfaces 232 downwardly extend from the inner edge 231 of the peripheral wall 23. The four inner lateral surfaces 223 completely surround the acoustic wave transducer 30 and the ASIC 40. The inner top surface 222 and the inner lateral surfaces 223 are all in a holeless structure which means that there is no hole on the inner top surface 222 and the inner lateral surfaces 232. In the present embodiment, the inner top surface 222 and the inner lateral surfaces 232 each are all shaped in a complete rectangular. The lid 20 further has an electromagnetic shielding structure 50 and at least two first metal layers 28a,28b. The electromagnetic shielding structure 50 completely covers the whole area of the inner top surface 222 and the inner lateral surfaces 232 by means of coating so as to form three-dimensional shielding. The first metal layers 28a,28b are embedded in the peripheral wall 23 and are extended to an interior of the plate portion 22. Specifically, the first metal layers 28a are located at four corners of the peripheral wall 23. The first metal layers 28b comprises via holes 281 that are spacedly located between two of the corners of the peripheral wall 23. The first metal layer 28a is employed for grounding and electrically connected with the three-dimensional electromagnetic shielding structure 50, while the first metal layer 28b is employed for signal transmission. The electromagnetic shielding structure 50 is electrically insulated with the ASIC 40. When the lid 40 is adhered to the top surface 11 of the circuit substrate 10 via conducting resin (not shown in the drawings), the first metal layer 28b can be electrically connected with the electric connection structures 18b which are served for signal transmission. Furthermore, the electromagnetic shielding structure 50 can be electrically connected with the electric connection structures 18a via conducting resin.

The acoustic wave transducer 30 and the ASIC 40 are mounted in the cavity 26 and on the top surface 11 of the circuit substrate 10. The acoustic wave transducer 30 corresponds to the sound hole 13. As acoustic wave passes through the sound hole 13, the acoustic wave transducer 30 can generate an electrical signal and send the generated electrical signal to the solder pad 25b via the ASIC 40, the electric connection structures 18b, and the first metal layer 28b.

The solder pads 25a,25b are arranged on the top of the plate portion 22 and the solder pads 25a,25b are served for grounding and signal transmission respectively. The solder pads 25a served for grounding are electrically connected with the first metal layer 28a. The solder pads 25b served for signal transmissions are electrically connected with the first metal layer 28b.

The metallic shielding layer 60 is completely arranged on the bottom surface 12 of the circuit substrate 10 and surrounded the sound hole 13. The metallic shielding layer 60 is electrically connected with the electromagnetic shielding structure 50 via the electric connection structure 18a. Thus, the electromagnetic shielding structure 50 and the metallic shielding layer 60 can almost enclose the acoustic wave transducer 30 and the ASIC 40, facilitating preventing the acoustic wave transducer 30 and the ASIC 40 from external electromagnetic interference. In some embodiment, the metallic shielding layer 60 may be completely covered on the central portion 10a, where the acoustic wave transducer 30 and the ASIC 40 locate. The electromagnetic shielding structure 50 and the metallic shielding layer 60 can still provide a satisfactory shielding effect to prevent external electromagnetic interference.

When the MEMS microphone package structure 1 receives an acoustic wave through the sound hole 13, the acoustic wave transducer 30 vibrates and generates an electrical signal. Then, the generated electrical signal is transmitted through the ASIC 40, the electric connection structures 18b and the first metal layer 28b to the solder pad 25b. Under the circumstances that the whole area of the inner top surface 222 and the inner lateral surfaces 232 are completely disposed by the electromagnetic shielding structure 50, the electromagnetic shielding structure 50 is holeless in structure and the bottom of the circuit substrate 10 is covered by the metallic shielding layer 60, the acoustic wave transducer 30 and the ASIC 40 can be better protected from external electromagnetic interference.

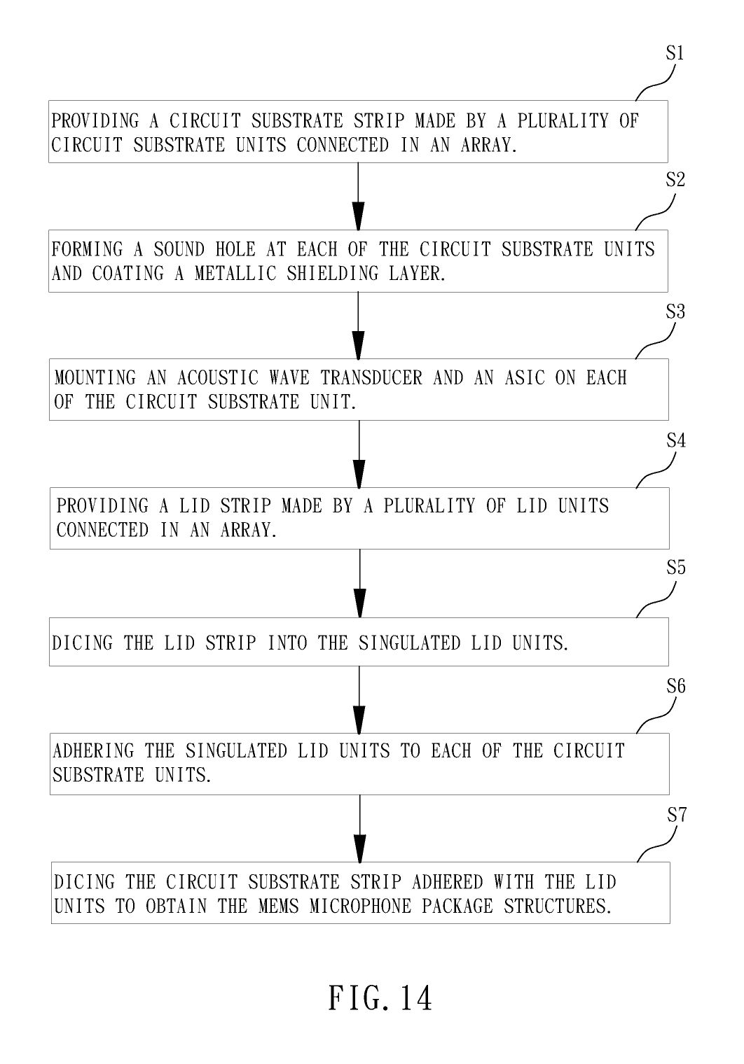

With reference to FIG. 14, a method for manufacturing the MEMS microphone package structures 1 of the present embodiment is provided to have the following steps. It should be noted that the sequence of the following steps can be changed. For example, the Step S1-S3 can be performed after the Step S4-S6. The details of each step are described as follows.

S1: providing a circuit substrate strip which is made by a plurality of circuit substrate units 10 arranged and connected in an array. Each of the circuit substrate units 10 has a top surface 11, a bottom surface 12 and some electric connection structures 18a,18b arranged and embedded in an interior of the respective circuit substrate unit 10.

After the Step 51, performing Step S2: forming a sound hole 13 at each of the circuit substrate units 10 and coating a metallic shielding layer 60 on each of the circuit substrate units 10. It is noted that the sound hole 13 each passes through the top surface 11 and the bottom surface 12 of the respective circuit substrate unit 10.

After the Step S2, performing Step S3: mounting an acoustic wave transducer 30 and an ASIC 40 on each of the circuit substrate unit 10, electrically connecting the acoustic wave transducer 30 and the ASIC 40 (e.g. by wire bonding), and electrically connecting the ASIC 40 and electrical connection structure 18b (e.g. by wire bonding).

After the Step S3, performing Step S4: providing a lid strip which is made by a plurality of lid units 20 arranged and connected in an array. Each of the lid units 20 has a plate portion 22 and a peripheral wall 23 surrounding and downwardly extending from a periphery 221 of the plate portion 22. The lid units 20 further has two first metal layers 28a,28b served for grounding and signal transmission respectively and a plurality of inner surface (an inner top surface 222 and four inner lateral surface 232) which are all completely covered by an electromagnetic shielding structure 50. The four inner lateral surfaces 232 surrounds an inner edge of the inner top surface 222 and downwardly extends from the inner edge of the inner top surface 222. In the present embodiment, the electromagnetic shielding structure 50 is disposed by coating.

After the Step S5, performing Step S6: dicing the lid strip into the plurality of singulated lid units 20.

After the Step S6, performing Step S7: adhering each of the singulated lid units 20 to each of the circuit substrate units 10 in such a way that the acoustic wave transducer 30 and the ASIC 40 are completely surrounded and covered by the electromagnetic shielding structure 50. The first metal layer 28b is electrically connected with the electric conducting structure 18b served for signal transmission via conducting resin, and the first metal layer 28a is electrically connected with the electric connection structure 18a served for grounding via conducting resin.

After the Step S7, performing Step S8: dicing the circuit substrate strip which is adhered with the plurality of the lid units 20 to obtain each of the MEMS microphone package structures 1.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A MEMS microphone package structure, comprising:
a circuit substrate having a top surface, a bottom surface, and a sound hole passing through the top surface and the bottom surface;
a metallic shielding layer arranged on the bottom surface of the circuit substrate and surrounded the sound hole;
an acoustic wave transducer being disposed on the top surface;
an application-specific integrated circuit being disposed on the top surface and electrically connected with the acoustic wave transducer;
a three-dimensional lid being made by a multilayer printed circuit boards and comprising a plate portion and a peripheral wall downwardly extending from a periphery of the plate portion, the three-dimensional lid further having a plurality of inner surfaces, at least two first metal layers embedded in the peripheral wall and served for signal transmission and grounding respectively, and an electromagnetic shielding layer covering the plurality of the inner surfaces; and
at least two solder pads disposed on the lid and electrically connected with the at least two first metal layers served for signal transmission and grounding respectively.

2. The MEMS microphone package structure as claimed in claim 1, wherein the first metal layer served for signal transmission further comprises a via, and the first metal layer served for signal transmission is electrically connected with the circuit substrate by the via.

3. The MEMS microphone package structure as claimed in claim 1, wherein the circuit substrate further includes an embedded electric connection structure; the metallic shielding layer is electrically connected with the first metal layer served for grounding via the embedded electric connection structure.

4. The MEMS microphone package structure as claimed in claim 1, wherein the circuit substrate further comprises a central portion for carrying the acoustic wave transducer and the application-specific integrated circuit and a peripheral portion surrounding the central portion; the metallic shielding layer is completely covered on the central portion.

5. The MEMS microphone package structure as claimed in claim 1, wherein the metallic shielding layer is completely covered on the bottom surface of the circuit substrate.

6. The MEMS microphone package structure as claimed in claim 1, wherein the electromagnetic shielding layer is electrically insulated with the application-specific integrated circuit.

7. The MEMS microphone package structure as claimed in claim 1, wherein the first metal layer served for grounding is arranged at a corner of the three-dimensional lid.

8. A method for manufacturing MEMS microphone package structures, comprising:
providing a circuit substrate strip which is made by a plurality of circuit substrate units arranged and connected in an array, coating a metallic shielding layer on each of the bottom surface of the circuit substrate units, forming a sound hole at each of the circuit substrate units, mounting an acoustic wave transducer on the circuit substrate unit each, mounting an application-specific integrated circuit on the circuit substrate unit each and electrically connecting the acoustic wave transducer;
providing a lid strip which is made by a plurality of lid units arranged and connected in an array, wherein each of the lid units is made by a multilayer printed circuit boards; the lid units each have a plurality of inner surfaces, at least two first metal layers embedded in the peripheral wall and served for signal transmission and grounding respectively, and an electromagnetic shielding layer covering the plurality of the inner surfaces; dicing the lid strip into the plurality of the singulated lid units;
adhering the singulated lid units to each of the circuit substrate units of the circuit substrate strip;
dicing the circuit substrate strip adhered with the singulated lid units to obtain the MEMS microphone package structures.

9. The method for manufacturing MEMS microphone package structures as claimed in claim 8, wherein each of the singulated lid units are respectively adhered to the lid units by conducting resin.

10. The method for manufacturing MEMS microphone package structures as claimed in claim 8, wherein the first metal layer served for signal transmission is electrically connected with the circuit substrate unit by conducting resin.

11. The method for manufacturing MEMS microphone package structures as claimed in claim 8, wherein the acoustic wave transducer is electrically connected with the application-specific integrated circuit by wire bonding and the application-specific integrated circuit is electrically connected with the circuit substrate unit by wire bonding.
